(19) United States
(12) Patent Application Publication
(10) Pub. No.: US 2017/0012154 A1
(43) Pub. Date: Jan. 12, 2017

(54) METHOD FOR PRODUCING SOLAR CELLS AND SOLAR CELL ASSEMBLIES

(71) Applicant: SolAero Technologies Corp., Albuquerque, NM (US)

(72) Inventors: Daniel Aiken, Cedar Crest, NM (US); Marvin Clevenger, Albuquerque, NM (US)

(73) Assignee: SolAero Technologies Corp., Albuquerque, NM (US)

(21) Appl. No.: 15/081,123

(22) Filed: Mar. 25, 2016

Related U.S. Application Data
(60) Provisional application No. 62/190,441, filed on Jul. 9, 2015.

(51) Int. Cl. H01L 31/0475; B64G 1/44; H02S 10/40

(52) U.S. Cl. CPC H01L 31/0475; H02S 10/40; B64G 1/443

(57) ABSTRACT

Solar cells are obtained by singulating a non-rectangular solar cell wafer into a plurality of solar cells, in one embodiment a first solar cell having a surface area corresponding to at least 60% of the wafer surface area but less than 90% of the wafer surface area, and at least two second solar cells each having a surface area of less than 10% of the wafer surface area. Such a first solar cell can be connected in parallel with a plurality of the second solar cells, to establish a substantially rectangular subassembly, and such subassemblies can be combined into a larger solar cell assembly, which may be mounted on a support including other electrical components on the backside thereof, and attached to a small satellite (e.g., CubeSat) exterior surface, or deployable wing.

### REFERENCE TO RELATED APPLICATIONS

This application claims the benefit of U.S. Provisional Patent Application No.

62/190,441 filed Jul. 9, 2015.

This application is related to U.S. Patent Application Ser. Nos. 14/498,071 filed Sep. 26, 2014, now U.S. Pat. No. ______ and its divisional application Ser. No. 15/014,667 filed Feb. 6, 2016.

This application is also related to U.S. patent application Ser. No. 14/514,883 filed Oct. 14, 2014.

This application is also related to U.S. patent application Ser. No. 14/151,236 filed Jan. 9, 2014.

This application is also related to U.S. patent application Ser. No. 15/058,805 filed Mar. 2, 2016.

This application is also related to U.S. Patent Application Ser. Nos. 29/505,800 and 29/505,801 filed Feb. 17, 2016.

Each of the above applications are hereby incorporated by reference.

### BACKGROUND OF THE DISCLOSURE

1. Field of the Disclosure

The disclosure relates to the field of photovoltaic power devices, and more particularly arrays of discrete solar cells assembled on a panel.

2. Description of the Related Art

Photovoltaic devices, such as photovoltaic modules or CIC (Solar Cell+Interconnects+Coverglass) devices, comprise one or more individual solar cells arranged to produce electric power in response to irradiation by solar light. Sometimes, the individual solar cells are rectangular, often square. Photovoltaic modules, arrays and devices including one or more solar cells may also be substantially rectangular, for example, based on an array of individual solar cells. Arrays of substantially circular solar cells are known to involve the drawback of inefficient use of the surface on which the solar cells are mounted, due to space that is not covered by the circular solar cells due to the space that is left between adjacent solar cells due to their circular configuration (cf. U.S. Pat. Nos. 4,235,643 and 4,321,417).

However, solar cells are often produced from circular or substantially circular wafers. For example, solar cells for space applications are typically multijunction solar cells grown on substantially circular wafers. These circular wafers are sometimes 100 mm or 150 mm diameter wafers. However, as explained above, for assembly into a solar array (henceforth, also referred to as a solar cell assembly), substantially circular solar cells, which can be produced from substantially circular wafers to minimize wasting wafer material and, therefore, minimize solar cell cost, are often not the best option, due to their low array packing factor, which increases the overall cost of the photovoltaic may or panel and implies an inefficient use of available space.

Therefore the circular wafers are often divided into other form factors to make solar cells. One preferable form factor for a solar cell for space applications is a rectangle, such as a square, which allows for the area of a rectangular panel consisting of an array of solar cells to be filled 100% (henceforth, that situation is referred to as a “packing factor” of 100%), assuming that there is no space between the adjacent rectangular solar cells. However, when a single circular wafer is divided into a single rectangular solar cell, the wafer utilization is low. This results in waste of the solar cell wafer material. This is illustrated in FIG. 1, showing how conventionally, out of a circular solar cell wafer 100 a rectangular solar cell 1000 is obtained, leaving the rest of the wafer as waste 1001. This rectangular solar cell 1000 can then be placed side by side with other rectangular solar cells 1000 obtained from other wafers, thereby providing for efficient use of the surface on which the solar cells are placed (i.e., high packing factor): a large watt to square meter or W/m² ratio can be obtained, which depending on the substrate may also imply a high W/kg ratio, of great importance for space applications. That is, closely packed solar cells without any space between the adjacent solar cells is generally preferred, and especially for applications in which W/m² and/or W/kg are important aspects to consider, This includes space applications, such as solar power devices for satellites.

Space applications frequently use high efficiency solar cells, including multijunction III/V compound semiconductor solar cells. High efficiency solar cell wafers are often costly to produce. Thus, the waste that has conventionally been accepted in the art as the price to pay for a high packing factor, that is, the waste that is the result of cutting the rectangular solar cell out of the substantially circular solar cell wafer, can imply a considerable cost.

Thus, the option of using substantially circular solar cells, corresponding to substantially circular solar cell wafers, to produce an array or assembly of solar cells, could in some cases become an interesting option. There is a trade-off between maximum use of the original wafer material and the packing factor. FIG. 2 shows how circular wafers can be packed according to a layout for maximum use of space, obtaining a packing factor in the order of 90%. This implies less wafer material is wasted than in the case of the option shown in FIG. 1, but also a less efficient use of the surface on which the solar cells are mounted, due to the lower packing factor. A further problem is that with this kind of layout, the pattern features a staggered distribution (schematically illustrated by the hexagon 2000 illustrated with broken lines in FIG. 2), which is non-optimal for producing a rectangular assembly of solar cells. The fact that the different rows of solar cells are staggered in relation to each other means that the assembly of solar cells will not fit neatly to the edges or boundaries of a rectangular panel. This implies an inefficient use of the space on the panel, which is problematic for space vehicles in which the available surface area is at a premium.

FIG. 3 schematically illustrates another approach, where an octagonal solar cell 1002 (also known as a “square solar cell with cropped corners)” is produced from a circular wafer 100. FIG. 3 shows how the solar cell 1002 fits into a square D. Square units are useful for building assemblies because they can be rotated, simplifying assembly, without disrupting the array pattern. FIG. 3 illustrates how a square unit is derived from a square solar cell with truncated corners. This approach represents an improved wafer utilization compared to the approach of FIG. 1 as the waste 1001 of wafer material is less (frequently wafer utilization in the order of 70-80% is achieved), but it achieves only a moderate packing factor, for example, in the order of 85-95%.

### SUMMARY OF THE DISCLOSURE

A first aspect of the disclosure relates to a method for producing solar cells, comprising the step of dividing a non-rectangular solar cell wafer having a wafer surface area into a plurality of solar cells, the plurality of solar cells comprising a first solar cell having a surface area corresponding to at least 70% of the wafer surface area but less than 90% of the wafer surface area, and at least two second solar cells each having a surface area of less than 10% of the wafer surface area. By dividing the wafer into solar cells having different sizes, a high wafer utilization can be achieved. The first and the second solar cells can then be combined to provide a subassembly having a shape appropriate for a certain purpose, such as a substantially rectangular (for example, square) shape that facilitates combination of the subassemblies into an assembly, with a high packing factor, for example, with a packing factor of 100% or close to 100%. For example, wafer utilization of more than 90% (that is, with less than 10% waste of wafer material) can be obtained in combination with a high panting factor of the final assembly, such as a packing factor of 100% or close to 100%. Also, the fact that one of the solar cells is relatively large, that is, corresponding to more than 60% of the wafer surface area, is advantageous in that it may reduce the number of interconnections and the costs involved therewith, compared to for example a situation in which a wafer is divided into a large number of small solar cells. That is, the combination of one relatively large and more than one relatively small solar cells has been found to allow for an enhanced overall efficiency when both wafer utilization, panel packing factor and cost of interconnection of the solar cells are taken into account.

In some embodiments of the disclosure, the first solar cell has a surface area of more than 75% of the wafer surface area, such as more than 80% of the wafer surface area.

In some embodiments of the disclosure, each of the second solar cells has a surface area of less than 8% of the wafer surface area, for example, less than 5% of the wafer surface area. Thus, the second solar cells can be used to fully or partly fill in the space of a rectangle, such as a square, partly filled by the first solar cell, thereby providing for a rectangular, such as square, subassembly with a high packing factor, such as with a packing factor of 100% or close to 100%. Such solar cell subassemblies can then be combined into a solar cell assembly likewise having a high packing factor.

In some embodiments of the disclosure, the first solar cell has a substantially polygonal shape with more than four sides. In some embodiments, the first solar cell has a substantially octagonal shape, for example, the shape of a rectangular, such as square, solar cell with cropped corners. That is, the present disclosure encompass for example the use of first solar cells in the form of square solar cells with cropped corners, whereby the second solar cells can be used to fill in the empty space left in correspondence with the corners when a solar cell assembly is built. Thus, wafer waste is reduced and the packing factor is enhanced.

In some embodiments of the disclosure, the first solar cell has a length and a width, the length being larger than the width. For example, the first solar cell can have a rectangular but non square shape, with cropped corners.

In some embodiments of the disclosure, the second solar cells have a substantially polygonal shape, for example, a substantially triangular shape. For example, second solar cells having a triangular shape have been found to be useful to fill in the empty space at the corners of larger solar cells having cropped corners, when these are combined to form a solar cell assembly.

In some embodiments, the wafer is divided into not more than five solar cells, for example, into not more than three solar cells, including the first solar cell and the second solar cells. In some embodiments, the use of a relatively small number of solar cells is preferred in order to minimize the number of interconnections in the subassembly.

In some embodiments of the invention, the solar cell wafer is a III-V compound semiconductor multijunction solar cell wafer. The relatively high cost of such wafer material may render the solar cell assemblies described in the present disclosure especially advantageous for many space applications, due to the reduction of waste without compromising packing factor and without any need for an excessive number of interconnections.

A second aspect of the disclosure relates to a method of fabricating a solar cell assembly, comprising the steps of singulating or dividing a plurality of non-rectangular solar cell wafers each having a wafer surface area into a plurality of discrete solar cells, said plurality of solar cells comprising a set of first solar cells each solar cell having a surface area corresponding to at least 60% of the wafer surface area but less than 90% of the wafer surface area, and a set including a plurality of second solar cells each solar cell having a surface area of less than 10% of the wafer surface area; and arranging said solar cells on a support forming an array of subassemblies, each subassembly having a substantially rectangular shape, each subassembly comprising one of the first solar cells and a plurality of the second solar cells, connected in parallel. As indicated above, high wafer utilization and a good panel or assembly packing factor, and the number of interconnections needed to connect the different solar cells in parallel can be kept relatively low, due to the use of one relatively large solar cell for each subassembly. What has been discussed in relation to the first aspect of the present disclosure applies also to the second aspect of the disclosure.

A third aspect of the disclosure relates to a solar cell assembly comprising a plurality of substantially rectangular subassemblies, each subassembly comprising a first solar cell having a nonrectangular shape and a surface area having a first size, and a plurality of second solar cells each having a surface area of less than a second size, the second size being less than ⅙ of the first size, the first and the second solar cells of each subassembly being electrically interconnected in parallel. The subassemblies can for example be arranged in rows and columns forming an array of subassemblies, for example, organized in strings of serially interconnected subassemblies. The subassemblies can be arranged on a support, forming a solar cell array panel. The advantages involved with the use of a combination of relatively large and small solar cells in terms of wafer utilization, assembly packing factor and cost of interconnection, have been noted above.

In another aspect, the present disclosure provides a space vehicle and its method of fabrication comprising: a payload disposed on or within the space vehicle; and a power source for the payload, including an may of solar cell assemblies mounted on a panel, each solar cell assembly being of the type described above.

In another aspect, the present disclosure provides a space vehicle including a photovoltaic array panel, in which the panel comprises the step of dividing a non-rectangular wafer into a plurality of solar cells including at least one solar cell having a first geometric configuration and at least one solar cell having a second geometric configuration, the second geometric configuration being different from the first geometric configuration.

In some embodiments, the at least one solar cell having the first geometric configuration has a rectangular shape and a first size, and wherein the at least one solar cell having the second geometric configuration has a rectangular shape and a second size, the second size being different from the first size.

In some embodiments, the first size is a multiple of the second size.

In some embodiments, the plurality of solar cells further comprises at least one solar cell having a rectangular shape and a third size, the third size being different from the first size and the second size, the first size being a multiple of the third size.

In some embodiments, the at least one solar cell having the first geometric configuration is shaped as a rectangle having a first length and a first width, and wherein the at least one solar cell haying the second geometric configuration is shaped as a rectangle having a second length and a second width, wherein the first length is equal to said second length, and the first width is different from the second width, or the first length is different from the second length, and the first width is equal to the second width.

In some embodiments, the plurality of solar cells comprise in solar cells having the first geometric configuration, and n solar cells having the second geometric configuration, m and n both being integers larger than 10, preferably larger than 20.

In some embodiments, the assembly of solar cells has a substantially rectangular configuration.

In some embodiments, the set of solar cells is disposed in a series connection comprising at least a first stage and a second stage, each connected in a series, the first stage comprising a different number of solar cells than the second stage.

In some embodiments, the effective surface area of the first stage and the effective surface area of the second stage have substantially the same size.

In some embodiments, the plurality of solar cells comprises one first solar cell and at least two second solar cells, each second solar cell having a surface area of less than 10% of the wafer surface area, characterized in that the first solar cell has a surface area corresponding to at least 70% of the wafer surface area but less than 90% of the wafer surface area.

In some embodiments, the first solar cell has a surface area of more than 75% of the wafer surface area.

In some embodiments, the first solar cell has a surface area of more than 80% of the wafer surface area.

In some embodiments, each of the second solar cells has a surface area of less than 8% of the wafer surface area.

In some embodiments, each of the second solar cells has a surface area of less than 5% of the wafer surface area.

In some embodiments, the first solar cell has a substantially polygonal shape with more than four sides.

In some embodiments, the first solar cell has a substantially octagonal shape.

In some embodiments, the first solar cell has a length and a width, the length being larger than the width.

In some embodiments, the second solar cells have a substantially polygonal shape.

In some embodiments, the wafer is divided into not more than five solar cells.

In some embodiments, the solar cell wafer is a III-V compound semiconductor multijunction solar cell wafer.

In some embodiments, a plurality of no solar cell wafers each having a wafer surface area is singulated into a plurality of solar cells, said plurality of solar cells comprising first solar cells each having a surface area corresponding to at least 60% of the wafer surface area but less than 90% of the wafer surface area, and a plurality of second solar cells each having a surface area of less than 10% of the wafer surface area.

In some embodiments, the solar cells am arranged on a support forming an array of subassemblies, each subassembly having a substantially rectangular shape, each subassembly comprising one of the first solar cells and a plurality of the second solar cells, connected in parallel.

In some embodiments, there comprises a plurality of substantially rectangular subassemblies, each subassembly comprising a first solar cell having a nonrectangular shape and a surface area having a first size, and a plurality of second solar cells each having a surface area of less than a second size, the second size being less than ⅙ of the first size, the first and the second solar cells of each subassembly being electrically interconnected in parallel.

In some embodiments, the second size is less than 1/10 of the first size.

In some embodiments, the first solar cell has a substantially polygonal shape with more than four sides.

In some embodiments, the first solar cell has a substantially octagonal shape.

In some embodiments, the first solar cell has a lengthy and a width, the length being larger than the width.

In some embodiments, the second solar cells have a substantially polygonal shape.

In some embodiments, the second solar cells have a substantially triangular shape.

in some embodiments, the space vehicle is a CubeSat.

In some embodiments, the deployable panel is stored within a one unit CubeSat housing for a space vehicle in its stowed configuration prior to deployment.

In some embodiments, the panel is mounted on the side of the CubeSat.

In some embodiments of the disclosure, the second size is less than 1/10 of the first size. As explained above, a large solar cell can be combined with relatively small solar cells to form the array, obtaining a high packing factor while minimizing wafer waste.

In some embodiments of the disclosure, the first solar cell has a substantially polygonal shape with more than four sides, such as a substantially octagonal shape.

In some embodiments of the disclosure, the first solar cell has a length and a width, the length being larger than the width. For example, the first solar cell can be a non-square rectangular solar cell.

In some embodiments of the disclosure, the second solar cells each have substantially polygonal shape, for example, a substantially triangular shape.

In some embodiments of the disclosure, the solar cells are III-V compound semiconductor multijunction solar cells.

Some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teachings herein will recognize additional applications, modifications and embodiments in other fields, which are within the scope of the disclosure and disclosed and claimed herein and with respect to which the disclosure could be of utility.

### BRIEF DESCRIPTION OF THE DRAWINGS

To complete the description and in order to provide for a better understanding of the disclosure, a set of drawings is provided. Said drawings form an integral part of the description and illustrate embodiments of the disclosure, which should not be interpreted as restricting the scope of the disclosure, but just as examples of how the disclosure can be carried out. The drawings comprise the following figures:

FIG. 1 schematically illustrates a prior art arrangement for producing a closely packed solar cell array out of square solar cells obtained from a circular solar cell wafer.

FIG. 2 schematically illustrates how circular solar cells packed to obtain a maximum packing factor imply a staggered arrangement of solar cells in an array of solar cells, or a solar cell assembly.

FIG. 3 schematically illustrates another prior art arrangement, based on the use of square solar cell with cropped corners obtained from a circular wafer.

FIG. 4A schematically illustrates how a substantially circular solar cell wafer can be divided into one relatively large first solar cell and a plurality of relatively small solar cells, it accordance with one embodiment of the disclosure.

FIG. 4B schematically illustrates how the solar cells obtained in accordance with FIG. 4A can be combined into a subassembly of rectangular shape, with a high packing factor.

FIG. 5A schematically illustrates how a substantially circular solar cell wafer can be divided into one relatively large first solar cell and a plurality of relatively small solar cells, in accordance with another embodiment of the disclosure.

FIG. 5B schematically illustrates how the solar cells obtained in accordance with FIG. 5A can be combined into a subassembly of rectangular shape, with a high packing factor.

FIG. 6 schematically illustrates a solar cell assembly comprising a plurality of solar cell subassemblies, in accordance with an embodiment of the disclosure.

FIG. 7 schematically illustrates the relation between panel power density and cost per watt for different solar cell arrangements.

FIGS. 8A-8C schematically illustrate three further embodiments of the disclosure.

FIG. 9 is a graph schematically illustrating the relationship between packing factor and use of wafer surface, in relation to some embodiments of the disclosure.

FIG. 10 is a perspective view of a CubeSat space vehicle incorporating one embodiment of a solar cell assembly according to the present disclosure.

### DETAILED DESCRIPTION

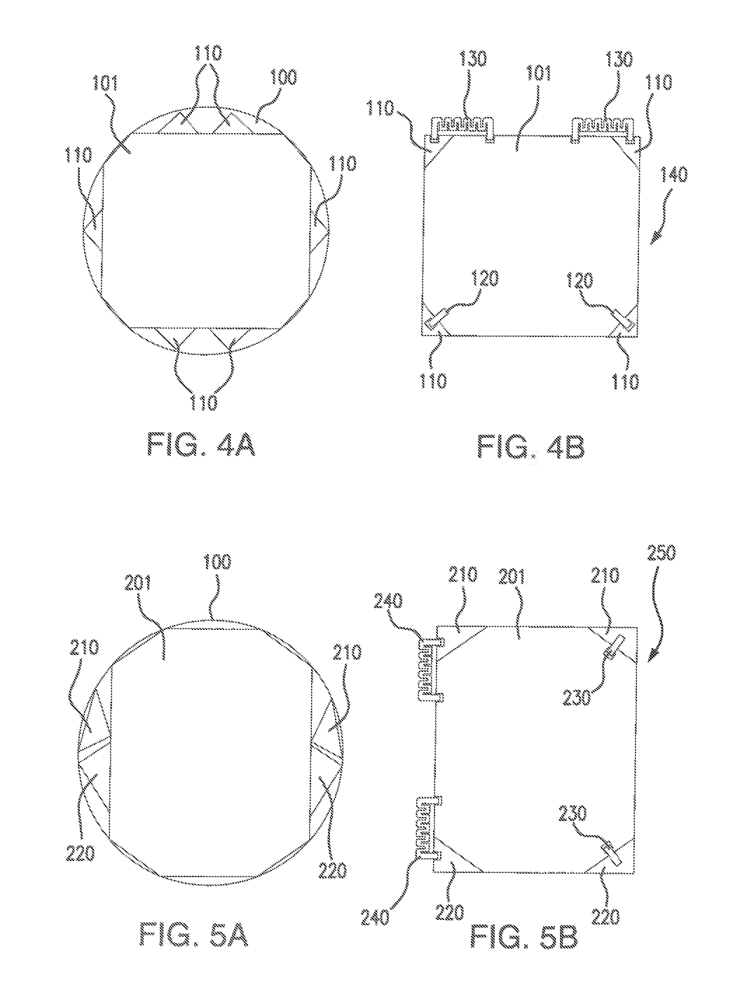

FIG. 4A schematically illustrates how 4 circular wafer 100 can be subdivided into one relatively large first solar cell 101, in this case having an octagonal shape, and a plurality of relatively small second solar cells 110, each having a substantially triangular shape. FIG. 4B schematically illustrates how the first solar cell 101 and four of the second solar cells 110 can be arranged to form a rectangular subassembly 140, in which the first solar cell 101 and the second solar cells 110 are connected in parallel, by interconnects 120 and 130. Interconnects 130 are arranged for further interconnecting the subassembly in series with another subassembly when forming a solar cell assembly out of the subassemblies. It is clear from FIGS. 4A and 4B that a high wafer utilization is achieved (as wafer material outside the first octagonal solar cell 101 is used for making the further, second, solar cells), and that a subassembly 140 with high packing factor is achieved, namely, with 100% (or close to 100%) packing factor. The rectangular shape of the subassembly 140 makes the subassembly suitable for the manufacture of a solar cell assembly featuring a likewise high packing factor, also known as panel packing factor.

FIG. 5A schematically illustrates another embodiment of the disclosure, in which a circular wafer is subdivided into one relatively large first solar cell 201 having a length larger than its width and with an octagonal shape, and four relatively small second solar cells 210 and 220, two of which are slightly larger than the other two. That is, it is not necessary that all of the second solar cells have the same size or shape. FIG. 5B schematically illustrates how the first solar will 201 and the second solar cells 210 and 220 can be arranged to form a rectangular subassembly 250, in which the first solar cell 201 and the second solar cells 210 and 220 are connected in parallel, by interconnects 230 and 240. Interconnects 240 are arranged for further interconnecting the subassembly in series with another subassembly. It is clear from FIGS. 5A and 5B that also in this embodiment a high wafer utilization is achieved (as wafer material outside the first octagonal solar cell 201 is used for making the further, second, solar cells), while a subassembly 250 with high packing factor is achieved, namely, with 100% (or close to 100%) packing factor. Also here the rectangular shape of the subassembly 250 makes the subassembly suitable for the manufacture of a solar cell assembly featuring a likewise high packing factor.

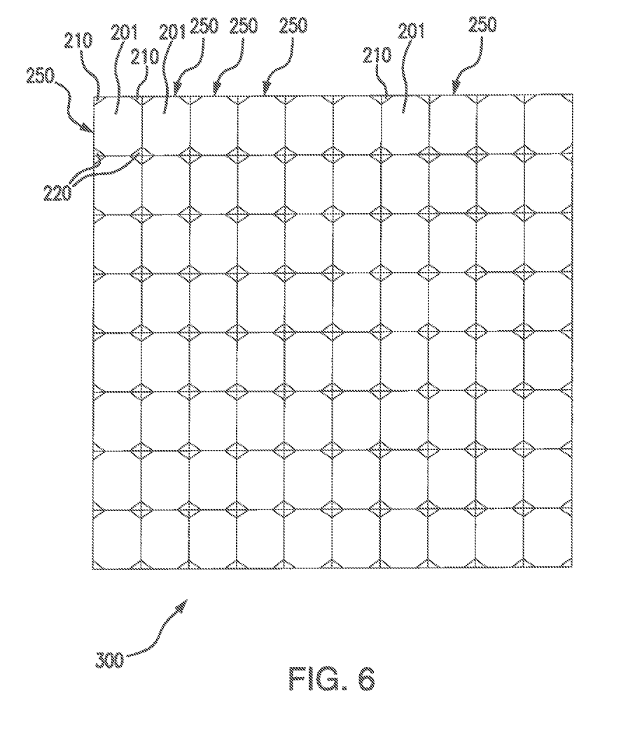

FIG. 6 schematically illustrates a solar cell assembly 300 or solar array panel comprising a matrix of solar cell subassemblies 250 as per the embodiment illustrated in FIG. 5B. As schematically illustrated in FIG. 6, due to the rectangular shape of the subassemblies 250, also the combination of such subassemblies can feature a high packing factor of 100% or close to 100%.

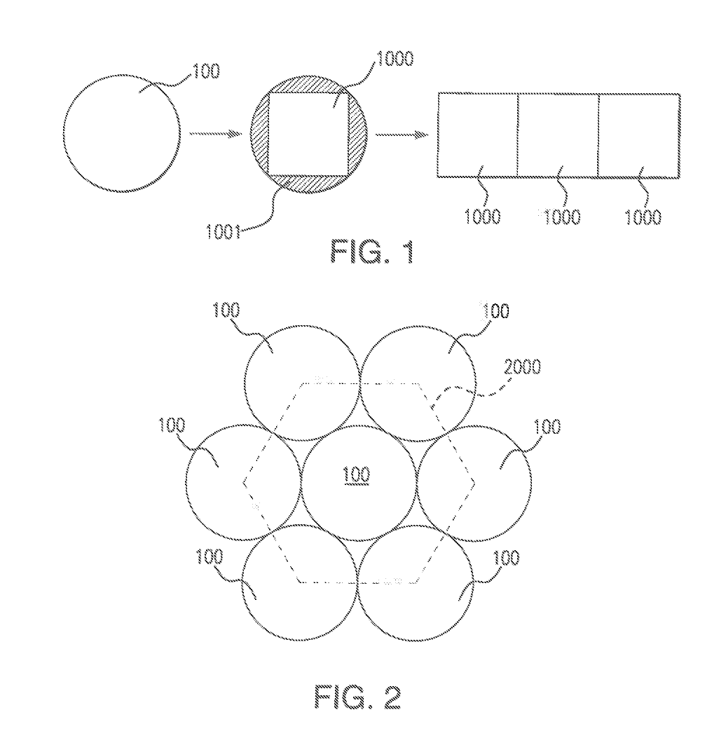

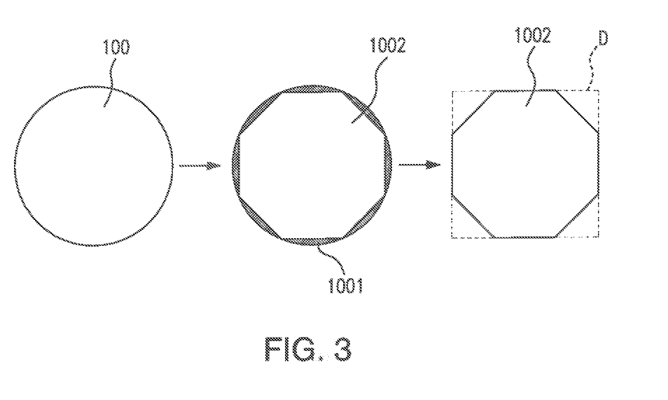

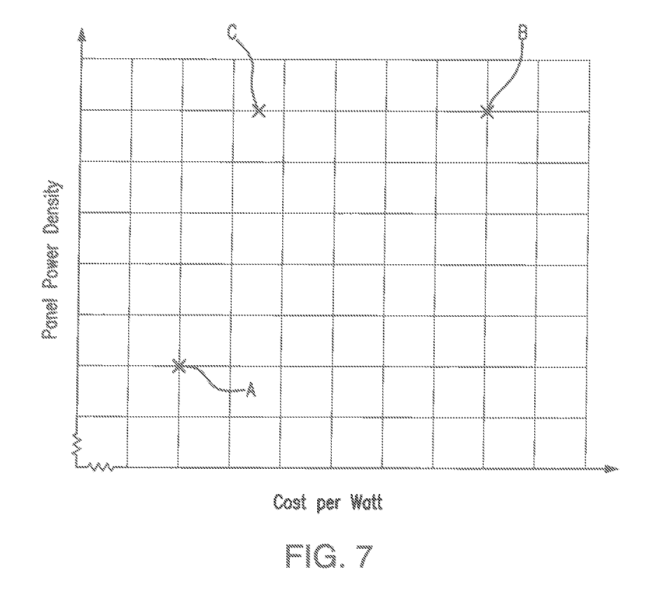

FIG. 7 is a schematic diagram in which the cost per watt for the solar cell corresponds to the horizontal axis, and the panel power density corresponds to the vertical axis. Case A corresponds to the case suggested in FIG. 2, when circular solar cells are used, with no loss of wafer material. This provides for a low cost per watt when the cell is considered, but also for a relatively low packing factor and thus a relatively low power density when the entire assembly or panel is considered. Case B corresponds to the case suggested in FIG. 1, where perfectly rectangular solar cells are cut out of a substantially circular wafer. The waste of wafer material implies a relatively high cost per watt, but the high packing factor (about 100%) that can be achieved provides for a high panel power density. On the other hand, case C corresponds to the use of composite subassemblies in accordance with the principles of the present disclosure, where the reduced waste implies a lower cost per watt than case B but a higher cost per watt than case A (due to the fact that there is still some waste of wafer material and additionally a cost of interconnection of the first and second solar cells), whereas the same high panel power density can be obtained as in case B.

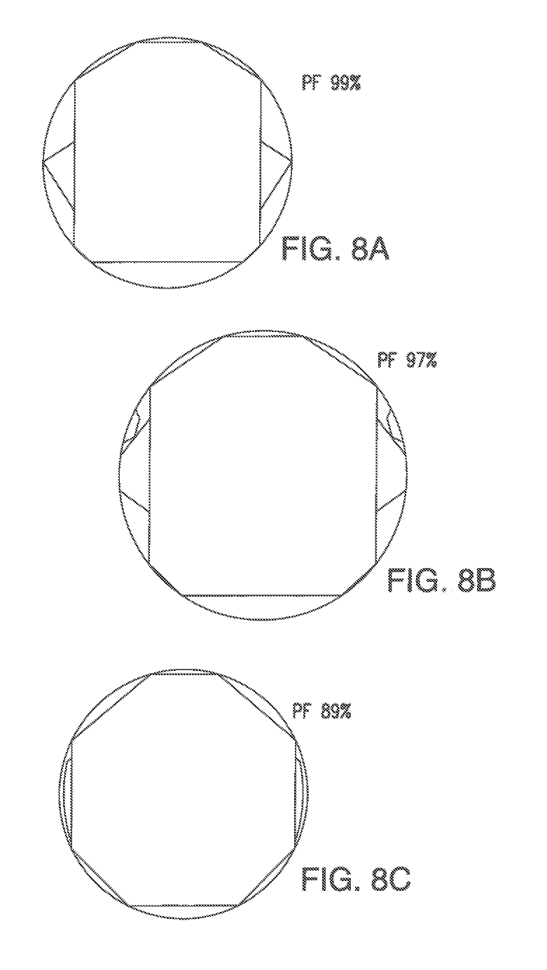

FIG. 8A illustrates a further embodiment of the disclosure. Also in this embodiment the first cell 810 has an octagonal configuration, and two second cells 811, 812 of triangular shape are cut out of the substantially circular wafer 800. The illustrated arrangement is estimated to provide for a packing factor of about 99%. However, it is clear that there is a substantial waste of wafer surface, which tends to increase the cost of the solar cell assembly.

The embodiment of FIG. 8B also features a first cell 810 having an octagonal layout, and four second sells, two larger ones 820, 821 and two smaller ones 822, 823. The estimated packing factor is 97%, that is, slightly less than the one of the embodiment of FIG. 8A, but the embodiment of FIG. 8B instead provides for a more efficient use of the material of the wafer 800, which contributes to a reduced cost in terms of the cost of the wafer material needed to provide a solar cell assembly with a given surface of solar cell material.

The embodiment of FIG. 8C makes even more efficient use of the wafer material. Also here, a first cell 830 having an octagonal shape is cut out of a substantially circular wafer 800, and two second cells 831, 832 are provided, each including a curved portion, substantially following the edge of the circular wafer. The embodiment of FIG. 8C visibly provides for an efficient use of wafer surface, thereby contributing to a reduced cost of the solar cell assembly in what regards the cost corresponding to wafer material. However, this has to be balanced against a lower packing factor, in this case estimated to be in the order of 89%.

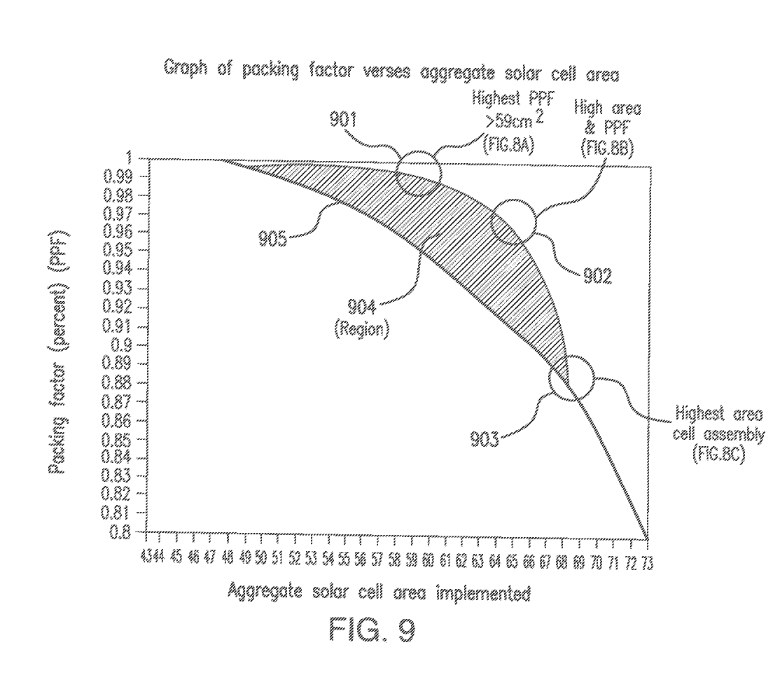

FIG. 9 schematically illustrates how the relation between the packing factor and the amount of used wafer surface area for a given wafer can be enhanced by implementing different embodiments of the disclosure. The horizontal axis represents the aggregate solar cell area, that is, the area of the wafer surface that is actually used for producing the corresponding solar cell subassembly, and the vertical axis represents the packing factor. The indicated numbers are not intended to represent a preferred embodiment, but are just indicated to simplify the understanding of the disclosure.

In the illustrated embodiment the diameter of the solar cell wafer is assumed to be a standard 100 mm. The total surface area of such a wafer is 78.5 square centimeters. Since normal fabrication processes exclude usage of a small portion of the edge of the wafer, the actual usable surface area to be singulated into individual solar cells is typically in the range of 70 to 75 square centimeters. The x-axis of FIG. 9 represents the aggregate solar cell area of such a wafer implemented under various singulation scenarios covered by the present disclosure, and third 70 to 73 square centimeters are tabulated on the far right end of the x-axis, corresponding to the maximum useable surface area.

The y-axis of FIG. 9 represents the “packing factor” or percentage of coverage of the local array area by the assembled pattern of singulated solar cells.

In FIG. 9, the curve 905 schematically represents different relations between packing factor and used amount of wafer surface that can be obtained by singulating or dicing solar cells out of a substantially circular wafer. As shown, generally, increased packing factor implies a less efficient use of wafer surface. The region 904 schematically represents how it is possible to expand beyond the boundaries of that basic curve 905 by implementing different embodiments of the disclosure, thereby enhancing the relationship between packing factor and used wafer surface area. In an exemplary embodiment, a very high packing factor combined with a reasonably efficient use of wafer surface area is represented at 901, which corresponds to the embodiment of FIG. 8A. 902 represents the embodiment of FIG. 8B. Here, the packing factor is not as good as in the case of the embodiment of FIG. 8A, but the use of wafer surface area has been improved. 903 represents the embodiment FIG. 8C, featuring a rather efficient use of wafer surface area but at the cost of a further reduced packing factor. Thus, FIG. 9 illustrates how different embodiments can be used to optimize the efficiency in terms of packing factor and use of wafer surface area. Thus, a person implementing the disclosure can choose an adequate embodiment depending on the importance of packing factor on one hand (for example, the importance of a high packing factor is greater when the power/weight ratio of the assembly is of great concern, such as in space applications), and efficient use of wafer material on the other (the importance of an efficient use of wafer material increases with the cost of the wafer material), in a given situation, subject to the constraint of limiting the number of singulated solar cells from a single wafer.

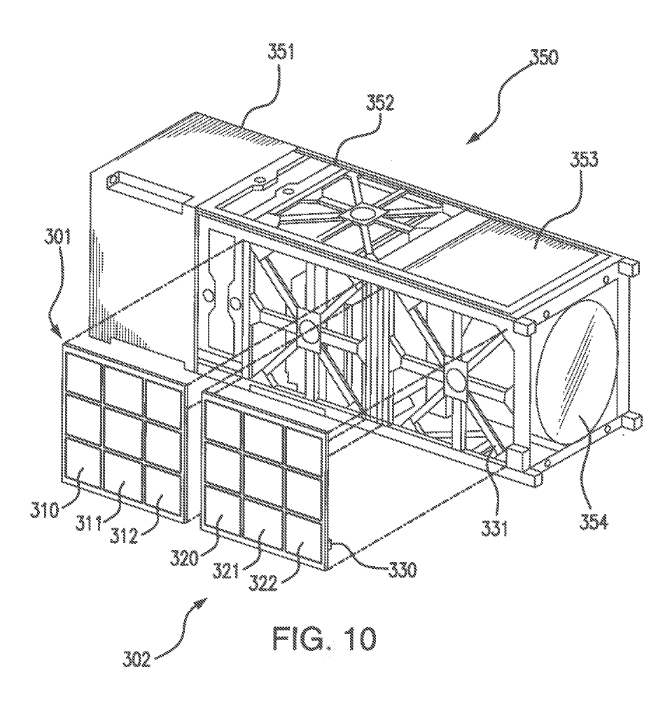

FIG. 10 illustrates a miniature satellite or CubeSat 350 according to the present disclosure. Solar assemblies as taught in the present disclosure, and in the related applications noted above may be mounted on supports 301, 302 which are then mounted on the CubeSat 350. CubeSats 350 are a type of miniaturized satellites or nanosatellite. A typical CubeSat is a 10 cm×10 cm×10 cm cube, thus having a volume of one liter. CubeSats can be attached to one another in strings or blocks to provide functionalities and capabilities that would not otherwise be practically available in a single CubeSat. FIG. 10 for example illustrates three individual CubeSats 351, 352, 353 forming a 3-unit CubeSat 350. For example, one CubeSat can be used to store a deployable photovoltaic array to supply power necessary for other attached. CubeSats to perform their functions. Reference may be made to U.S. patent application Ser. No. 14/921,238 filed. Oct. 23, 2015, herein incorporated by reference, depicting an embodiment of such a deployable solar cell array.

The solar cell assemblies described herein above can be particularly advantageous for attaching to a CubeSat. For example, the solar cell assembly can be attached directly to the surface of the support 301, 302 which are then mounted directly on the CubeSat without a need for a frame (e.g., an aluminum or honeycomb frame). Further, the solar cell supports 301, 302 can be composed of a light weight flexible support (e.g., a Kapton™ or other polyimide support) or a rigid and non-flexible support. The polyimide sheets as either a continuous layer or a patterned layer designed for a particular application. The base or backplane of the unit is typically a space qualified or qualifiable material (e.g., Kapton™, polyester, polyimide, Aramid™, Pyralux™) that is lightweight, flexible, and reliable in space applications, Kapton™ is a poly (4,4′-oxydiphenylene-pyromellitimide) material.

The different embodiments for attaching and bonding the solar cell assemblies to the support 301, 302 are described in U.S. patent application Ser. No. 14/795,461 filed Jul. 9, 2015. As noted therein, a pressure sensitive adhesive (PSA) layer or pattern may be applied.

In FIG. 10, we illustrate a panel 301 with an array of nine solar cell assemblies 310, 311, 312, etc. The solar cell assemblies 310, 311, 312 are depicted as substantially square and equally sized in the Figure to illustrate one embodiment. In another embodiment, solar cell assemblies 310 and 311 are of a first size or configuration, and solar cell assembly 312 is of a second size or configuration different from the first size or configuration. Other combinations or configurations, such as depicted in the present disclosure, may also be employed.

The packing factor referred to in this document is generally the local packing factor, which in many embodiments can differ from the overall packing factor of the solar cell assembly, for example due to a lower local packing factor in correspondence with the edges of the assembly (for example, due to the size and/or shape of the assembly), and/or due to the presence of other components on the solar cell assembly.

Another aspect of the present disclosure is to provide a suitable base or backplane support 301, 302 for the variety of solar cell assemblies described above to be mounted on CubeSat panel or extensible “wing”.

The backplane 301, 302 may be a sheet or may be patterned to it a specific application, such as a standard CubeSat at body panel, or to fit snugly around panel features such as hold-down release mechanisms or hinges. The backplane 301, 302 may contain no components or design features or may have certain features such as metal traces to allow it to interface, mechanically, electrically, or otherwise, to other modules or interconnections, terminal outputs, or related satellite features or components.

The backplane 301, 302 may be blank or may incorporate metallization applied through additive or subtractive processes that would enable or facilitate interconnection of solar cells into series and parallel arrangements, provide for the incorporation of bypass diodes, blocking diodes, bleed resistors, temperature sensors, and other applicable components 330 commonly incorporated into space solar arrays including end terminations, terminal outputs, or related features to interconnect the solar cells, cover glass interconnected cells (CICs), strings, or circuits on the backplane to other photovoltaic modules, to other panels, or to the satellite.

The backplane 301, 302 may incorporate or he joined with single-sided, or dual-sided pressure sensitive adhesive (PSA) on one or on both sides of the backplane. Frontside PSA may allow solar cells, CICs, or other components to be bonded or mounted onto the backplane 301, 302. Backside PSA may allow the backplane, which can be supporting solar cells, CICs, or other components, to be adhered to a solar panel that may be made of a rigid or flexible material, may be on a deployable wing for a satellite, or may be body-mounted to a satellite, as is the case for CubeSats, for example.

This backplane structure 301, 302 can enable the solar module to be self-adhesive through removal of a release liner or other protective film on one or both sides of the PSA-backplane followed by application of the module to the surface to which it is to be bonded.

The solar cells, CICs, and/or other components 310, 311, 312 to be incorporated into the module may be pre-assembled into free-standing assemblies, strings, or circuits, then bonded onto the backplane, by using frontside PSA or using some other adhesive material such as a silicone, which is commonly used in space solar panel manufacturing today, or by using solder, epoxy, or some similar material that can also provide electrical connection between the components and the backplane 301, 302 in the case that the backplane 301, 302 is metallized to support the function and/or interconnection of the components or modules. The assemblies, strings, or circuits can be subassemblies that may be assembled manually, or may be assembled in an automated fashion, in whole or in part, by one production machine, or by multiple production machines, and assembled onto, incorporated into, or combined with the backplane in a manual or an automated fashion.

Alternatively, the solar cells, CICs, and/or other components 310, 311, 312 to be incorporated into the module may be assembled, individually or as part of sub-assemblies, directly onto the backplane 301, 302, using similar methods to those described herein. The resulting assemblies, strings, or circuits made directly on the backplane 301, 302 may be assembled manually, or may be assembled in an automated fashion, in whole or in part, by one production machine or by multiple production machines.

The solar cells and other components 310, 311, 312 assembled into/onto the module may be of one uniform form factor (shape and size), or may be multiple and/or include a variety of form factors, and may be assembled with one uniform inter-component spacing, or a multiple and/or a variety of intra-components spacings as needed to best achieve the required specifications for the module, as taught by the present disclosure.

The components 310, 311, 312 may be interconnected by one uniform method, or by multiple and/or a variety of methods (e.g., wiring, interconnects, metal traces, wire/ribbon bonding, solder) as needed to achieve the performance, reliability, and/or other desired characteristics or required specifications for the module.

The completed module may optionally be coated, manually or by machine, with any of a variety of materials, including but not limited to transparent silicones, adhesives, conductive or insulating grouting between cells and/or other components, coverglass or other materials, as needed to achieve the performance, reliability, and/or other desired characteristics or required specifications for the module.

The CubeSat modules 351, 352, 353 may be any size or shape as needed to achieve the performance, reliability, and/or other desired characteristics or required specifications for the satellite or space vehicle. This means that a module can constitute an entire solar circuit or a partial circuit, can be connected in series or parallel to other module(s) to meet certain required performance specifications, such as an optical element 354.

In some embodiments, the module is envisioned to be consistent with the so-called CubeSat standard, such that CubeSat manufacturers and/or integrators can apply self-adhesive solar modules directly to their body mounted or deployable CubeSat panels.

In another embodiment, the module is envisioned to be one building block of a larger integrated unit in which solar panel or array manufacturers and/or integrators apply multiple self-adhesive solar modules directly to their body mounted or deployable solar panels, or rigid or flexible solar array structures. In this embodiment, the module can optionally be custom-designed to maximize utilization of the rigid or flexible solar panel and/or array structure to optimize power output, minimize mass, or otherwise meet certain required performance specifications.

In this text, the term “comprises” and its derivations (such as “comprising”, etc.) should not be understood in an excluding sense, that is, these terms should not be interpreted as excluding the possibility that what is described and defined may include further elements, steps, etc.

The disclosure is obviously not limited to the specific embodiment(s) described herein, but also encompasses any variations that may be considered by any person skilled in the art (for example, as regards the choice of materials, dimensions, components, configuration, etc.), within the general scope of the disclosure as defined in the claims.

1. A method for producing solar cells, comprising the step of dividing a non-rectangular solar cell wafer having a wafer surface area into a plurality of solar cells, the plurality of solar cells comprising one first solar cell and at least two second solar cells, each second solar cell having a surface area of less than 10% of the wafer surface area, characterized in that the first solar cell has a surface area corresponding to at least 70% of the wafer surface area but less than 90% of the wafer surface area.

2. The method of claim 1, wherein the first solar cell has a surface area of more than 75% of the wafer surface area.

3. The method of claim 2, wherein the first solar cell has a surface area of more than 80% of the wafer surface area.

4. The method of claim 1, wherein each of the second solar cells has a surface area of less than 8% of the wafer surface area.

5. The method of claim 4, wherein each of the second solar cells has a surface area of less than 5% of the wafer surface area,

6. The method of claim 1, wherein the first solar cell has a substantially polygonal shape with more than four sides.

7. The method of claim 6, wherein the first solar cell has a substantially octagonal shape.

8. A method of claim 1, wherein the first solar cell has a length and a width, the length being larger than the width.

9. A method of claim 1, wherein the second solar cells have a substantially polygonal shape.

10. A method of claim 1, wherein the wafer is divided into not more than five solar cells.

11. A method of claim 1, wherein the solar cell wafer is a multifunction III-V compound semiconductor solar cell wafer.

12. A solar assembly comprising:
a support; and
a plurality of solar cells mounted on the support, wherein a first set of the plurality of the solar cells have a first size and a second set of the plurality of solar cells have a second size different from the first size.

13. A solar cell assembly as defined in claim 12, wherein the plurality of solar cells are singulated from a solar cell wafer including first solar cells each having a surface area corresponding to at least 60% of the wafer surface area but less than 90% of the wafer surface area and a plurality of second solar cells each having a surface area of less than 10% of the wafer surface area;
the solar cells being mounted on the support and forming an array of subassemblies, each subassembly having a substantially rectangular shape, each subassembly comprising one of the first solar cells and a plurality of the second solar cells, connected in parallel.

14. A solar cell assembly as defined in claim 13, a plurality of substantially rectangular subassemblies, each subassembly comprising a first solar cell having a non-rectangular shape and a surface area having a first size, and a plurality of second solar cells each having a surface area of less than a second size, the second size being less than ⅙ of the first size, the first and the second solar cells of each subassembly being electrically interconnected in parallel.

15. The solar cell assembly of claim 12, wherein the second size is less than 1/10 of the first size.

16. The solar cell assembly of claim 12, wherein each solar cell in the first set of the plurality of solar cells has a substantially polygonal shape with more than four sides.

17. The solar cell assembly of claim 13, wherein each solar cell of the first set of solar cells has a length and a width, the length being larger than the width, and each solar cell in the second set of solar cells has a substantially triangular or polygonal shape.

18. A solar cell assembly as defined in claim 12, wherein the support has a fronst side on which the solar cells are mounted, and a backside including one or more of the following electronic or electrical components:
bypass diodes, blocking diodes, bleed resistors, temperature sensors, end terminations, and terminal outputs.

19. A solar cell assembly as defined in claim 12, wherein the support is sized to mount on a single CubeSat body panel.

20. A space vehicle including a photovoltaic array panel, in which the panel comprises a plurality of solar cells including at least one solar cell having a first geometric configuration and at least one solar cell having a second geometric configuration, the second geometric configuration being different from the first geometric configuration.
